(19) United States
(12) Patent Application Publication
(10) Pub. No.: US 2007/0020821 A1
(43) Pub. Date: Jan. 25, 2007

(54) METHOD FOR FORMING A THIN-FILM TRANSISTOR

(75) Inventor: Naoyuki Toyoda, Suwa (JP)

Correspondence Address: HARNESS, DICKEY & PIERCE, P.L.C., P.O. BOX 828, BLOOMFIELD HILLS, MI, 48303, US

(73) Assignee: Seiko Epson Corporation, Tokyo (JP)

(21) Appl. No.: 11/425,159

(22) Filed: Jun. 20, 2006

(30) Foreign Application Priority Data
Jul. 25, 2005 (JP) 2005-213796

(51) Int. Cl. H01L 21/84; H01L 21/00

(52) U.S. Cl. 438/149

(57) ABSTRACT

A method for forming a thin-film transistor includes forming a source electrode and a drain electrode on an element-side substrate, forming a semiconductor layer in contact with the source electrode and the drain electrode, forming a gate insulating layer overlaid on the semiconductor layer, and forming a gate electrode overlaid on the gate insulating layer, wherein the semiconductor layer is formed over a laser process at the step of forming the semiconductor layer in contact with the source electrode and the drain electrode.

### BACKGROUND OF THE INVENTION

1. Technical Field

The present invention relates to a method for forming a thin-film transistor.

2. Related Art

A thin-film transistor (TFT) containing an organic semiconductor layer as a channel layer is generally known. Since the so-called organic TFT functions even in a bent form, its application to a flexible sheet display and the like is expected.

An example of related art is disclosed in “Organic Transistor Technology Geared to Alignment Free Printing Production” by Masahiko Ando (printed in 2004, Research Group on Imaging Display and Materials, Compilation of Lecture Summary, The Society of Polymer Science, Japan, P16-21).

According to an existing method for forming the organic TFT, materials are placed differently based on whether the material of the organic semiconductor layer is low molecular or polymeric. For example, the materials are placed by a deposition method in a case of using the low molecular material while being placed by a printing method in a case of using the polymeric material. Herein, it would be convenient if there is a placement method not depending on material types, by which a simple modification of a production process is sufficient to change the material. Furthermore, a method for forming the organic semiconductor layer with use of a laser process is not known either.

### SUMMARY

One of advantages of the present invention is to provide a method for forming the thin-film transistor with use of the laser process.

According to an aspect of the invention, a method for forming a thin-film transistor includes the steps of forming a source electrode and a drain electrode on an element-side substrate, forming a semiconductor layer in contact with the source electrode and the drain electrode, forming a gate insulating layer overlaid on the semiconductor layer, and forming a gate electrode overlaid on the gate insulating layer. The semiconductor layer is formed over a laser process at the step of forming the semiconductor layer in contact with the source electrode and the drain electrode. For example, a first donor substrate having a first base substrate, a first ablation layer on the first base substrate, and a donor-side semiconductor layer on the first ablation layer is overlaid on the element-side substrate, and the first ablation layer is irradiated with a first laser beam in a manner to print at least one part of the donor-side semiconductor layer from the first donor substrate to the element-side substrate to obtain the semiconductor layer at the step for forming the semiconductor in contact with the source electrode and the drain electrode.

According to the aforementioned characteristics, the ablation layer becomes a sacrifice layer because of irradiation of the laser beam to the ablation layer, thereby being flaked, and thus at least one part of the donor-side semiconductor layer is printed to the element-side substrate to be a semiconductor layer. That is, the semiconductor layer can be obtained over the laser process, so that the thin-film transistor not depending on a material composing the semiconductor layer can be achieved.

In the aforementioned method, it is preferable that the element-side substrate having a substrate, a second ablation layer on the substrate, and a first conductive layer on the second ablation layer is prepared, and the second ablation layer is irradiated with a second laser beam in a manner to strip a portion other than the source electrode and the gate electrode off the first conductive layer at the step of forming the source electrode and the drain electrode on the element-side substrate.

In such a manner, the source electrode and the drain electrode can be formed over the laser process.

In the aforementioned method, furthermore, it is preferable that a second donor substrate having a second base substrate, a third ablation layer on the second base substrate, and an insulating layer on the third ablation layer is overlaid on the element-side substrate, and the third ablation layer is irradiated with a third laser beam in a manner to print at least one part of the insulating layer from the second donor substrate to the element-side substrate to obtain the gate insulating layer at the step of forming the gate insulating layer overlaid on the semiconductor layer.

In such a manner, the gate insulating film can be formed over the laser process.

In the aforementioned method, it is preferable that a third donor substrate having a third base substrate, a fourth ablation layer on the third base substrate, and a second conductive layer on the fourth ablation layer is overlaid on the element-side substrate, and the fourth ablation layer is irradiated with a fourth laser beam in a manner to print at least one part of the second conductive layer from the third donor substrate to the element-side substrate to obtain the gate electrode at the step of forming the gate electrode overlaid on the gate insulating layer.

In such a manner, the gate electrode can be formed over the laser process.

According to another aspect of the invention, a method for forming a thin-film transistor, includes the steps of forming a gate electrode on an element-side substrate, forming a gate insulating layer on the gate electrode, forming a semiconductor layer overlaid on the gate electrode, and forming a source electrode and a drain electrode in contact with the semiconductor layer, respectively. The semiconductor layer is formed over a laser process at the step of forming the semiconductor layer overlaid on the gate electrode. For example, a first donor substrate having the first base substrate, a first light-heat converting layer on the first base substrate, and a donor-side semiconductor layer on the first light-heat converting layer is overlaid on the element-side substrate, and the first light-heat converting layer is irradiated with a first laser beam in a manner to print at least one part of the donor-side semiconductor layer from the first donor substrate to the element-side substrate to obtain the semiconductor layer at the step of forming the semiconductor layer overlaid on the gate electrode.

According to the aforementioned characteristics, with heat caused by irradiation of the laser beam to the light-heat converting layer, at least one part of the donor-side semiconductor layer is evaporated or melted to be deposited or welded onto the element-side substrate, thereby being printed to be a semiconductor layer. That is, the semiconductor layer can be obtained over the laser process, so that the thin-film transistor not depending on a material composing the semiconductor layer can be achieved.

In the aforementioned method, the element-side substrate having a substrate, a first ablation layer on the substrate, and a first conductive layer on the first ablation layer is prepared, and the first ablation layer is irradiated with a second laser beam in a manner to strip a portion other than the gate electrode off the first conductive layer at the step of forming the gate electrode on the element-side substrate.

In such a manner, the gate electrode can be formed over the laser process.

In the aforementioned method, the a second donor substrate having a second base substrate, a light-heat converting layer on the second base substrate, and an insulating layer on the light-heat converting layer is overlaid on the element-side substrate, and the light-heat converting layer is irradiated with a third laser beam in a manner to print at least one part of the insulating layer from the second donor to substrate the element-side substrate to obtain the gate insulating layer at the step of forming the gate insulating layer on the gate electrode.

In such a manner, the gate insulating layer can be formed over the laser process.

In the aforementioned method, a third donor substrate having a third base substrate, a second ablation layer on the third base substrate, and a second conductive layer on the second ablation layer is overlaid on the element-side substrate, and the second ablation layer is irradiated with a fourth laser beam in a manner to print at least one part of the second conductive layer from the third donor substrate to the element-side substrate at the step of forming the source electrode and the drain electrode in contact with the semiconductor layer, respectively.

In such a manner, the source electrode and the drain electrode can be formed over the laser process.

### BRIEF DESCRIPTION OF THE DRAWINGS

The invention will be described with reference to the accompanying drawings, wherein like numbers reference like elements.

FIG. 1A to FIG. 1D are a schematic diagram showing a process for producing a TFT according to the first embodiment.

FIG. 2A to FIG. 2D are a schematic diagram showing a process for producing the TFT according to the first embodiment.

FIG. 3A to FIG. 3D are a schematic diagram showing a process for producing a TFT according to the second embodiment.

FIG. 4A to FIG. 4D are a schematic diagram showing a process for producing the TFT according to the second embodiment.

### DESCRIPTION OF EXEMPLARY EMBODIMENTS

Embodiments of the invention will be described.

### First Embodiment

Explained in this embodiment is a case where a method for forming a thin-film transistor according to the first embodiment of the invention is applied to produce a TFT of a top gate type.

1. Source Electrode and Drain Electrode

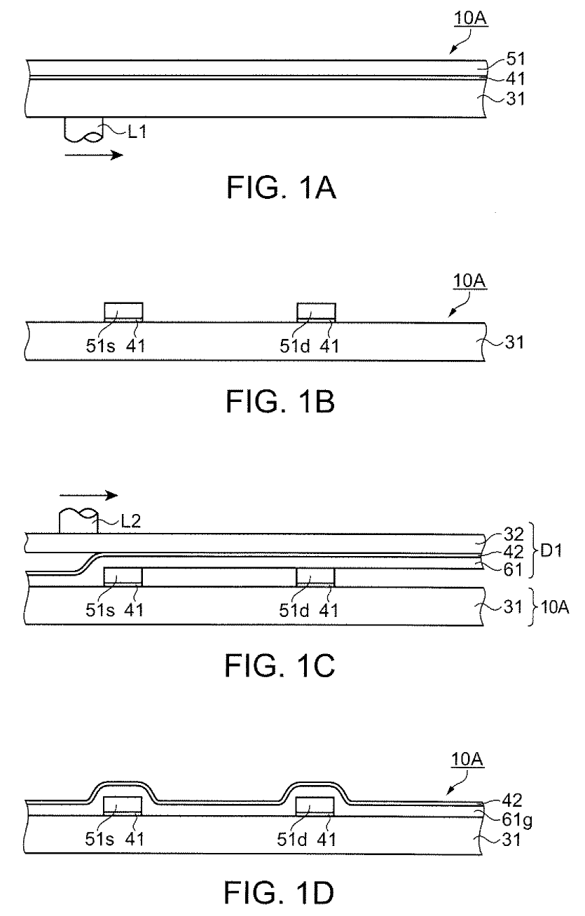

An element-side substrate 10A shown in FIG. 1A is prepared first. Herein, the element-side substrate 10A has a base substrate 31, an ablation layer 41 located on the base substrate 31, and a conductive layer 51 located on the ablation layer 41. The base substrate 31 is defined as a substrate permeable to light of wavelengths in an infrared region at least. The base substrate 31 is defined as a substrate made from polyimide in this embodiment. On the other hand, the ablation layer 41 is made from such materials that absorb laser light to cause ablation. The ablation layer contains materials which absorb wavelengths of laser radiation. In this embodiment, the ablation layer 41 is made from organic binders and carbons for absorbing light of wavelengths in the infrared region, and is formed in a printing process. This ablation layer 41 has a thickness of approximately 0.1 μm. The conductive layer 51 is made from chrome and is formed in a deposition process. The conductive layer 51 has a thickness of approximately 1.5 μm in the meanwhile, the material for absorbing light of wavelengths in the infrared region may be an infrared absorption dye other than carbon. To be more specific, phthalocyanine dye, naphthalocyanine dye, anthraquinone dye, indolenine dye, polymethine dye, squarylium dye, cyanine dye, metal complex dyestuff, azo cobalt complex dyestuff, thiol nickel complex dye, triarylmethane dye, immonium dye, naphthoquinone dye, anthracene dye, azulene dye, phthalide dye, and the like may be used.

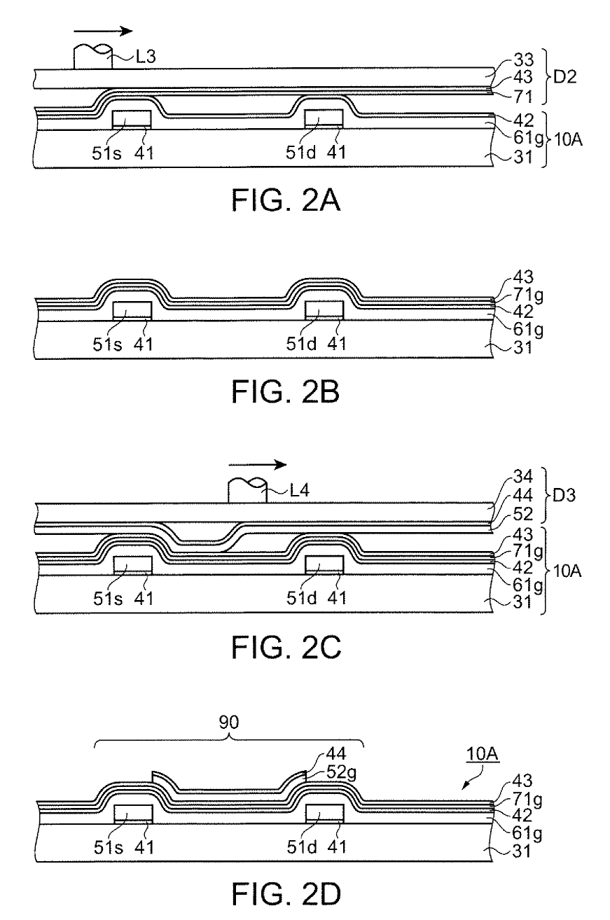

It is to be noted that the element-side substrate is a term used to express a combination of a substrate such as the base substrate 31 and at least a single layer or a pattern on the substrate. A TFT 90 shown in FIG. 2D is ultimately formed on the element-side substrate 10A in a case of this embodiment.

Next, a source electrode 51s and a drain electrode 51d are formed on the element-side substrate 10A in a laser process to be hereinafter described, as shown in FIG. 1A and FIG. 1B.

Specifically speaking, first, the element-side substrate 10A is set in a laser apparatus, not shown. An adjustment is then made to the laser apparatus so that a beam spot of laser beam L1 from the laser apparatus is located at a boundary surface between the base substrate 31 and the ablation layer 41. Furthermore, an intensity of the laser beam L1 is set so the laser beam L1 as to induce ablation of the ablation layer 41.

Herein, the laser apparatus according to this embodiment has a diode laser for giving off the laser beam L1, a scan optical system for two-dimensionally scanning the bean spot of the laser beam L1 on the boundary surface, and a computer. Herein, the laser beam L1 given off by the diode laser has a wavelength of 830 nm. Furthermore, the scan optical system has a beam expander, a galvanometer, and an f-θ lens, and is set so the beam spot of the laser beam L1 at the boundary surface as to have a diameter of 15 μm. The computer stores data corresponding to respective shapes of the constituent elements in the TFT, such as the source electrode 51s and the drain electrode 51d, and controls scan of the beam spot by the scan optical system. As is clear from explanation hereinafter, each of the constituent elements in the TFT is shaped by the scan of the beam spot according to the laser process in this embodiment. Therefore, each of the constituent elements can be shaped based on the data stored in the computer, directly.

The ablation layer 41 is irradiated with the laser beam L1 through the base substrate 31 by using the laser apparatus adjusted in the aforementioned manner. In this bout, the laser beam L1 is set to irradiate in accordance with shapes of the source electrode 31d and the drain electrode 51d to be formed. Herein, the ablation is caused at a portion of the ablation layer 41, on which the laser beam L1 is incident. Thus, the portion of the ablation layer 41, on which the laser beam L1 is incident, is eliminated from the base substrate 31 with accompanying the conductive layer 51. In this process, the laser beam L1 is therefore set to be incident on the corresponding portion other than the source electrode 51s and the drain electrode 51d, not on the portions corresponding to the source electrode 51s and the drain electrode 51d. The conductive layer 51 is eliminated with the portion to be set as the source electrode 51s and the portion to be set as the drain electrode 51d remaining in this manner.

In the meanwhile, it is preferable to irradiate the ablation layer 41 with the laser beam L1 under a high-vacuum or decompressed inert gas.

The source electrode 51s and the drain electrode 51d as shown in FIG. 1B are obtained in the aforementioned laser process. As described above, the use of the laser process renders a resist and a photomask unnecessary at the time of application of patterning to the source electrode 51s and the drain electrode 51d. It is to be noted that the ablation layer 41 remains between the source electrode 51s and the drain electrode 51d, and the base substrate 31 according to the laser process in this embodiment.

As described above, the laser process in this specification is defined as a process for scanning the ablation layer with the laser beam to apply patterning to a layer located on the ablation layer in a manner to form the layer in a predetermined shape. Alternatively, as described hereinafter, the laser process is also defined as a process for scanning the ablation layer with the laser beam to print a portion in a predetermined shape of the layer located on the ablation layer to another surface. It is to be noted that the ablation layer can be omitted in a case where the layer itself contains an ablative material. In another words, in this case, the laser process is the process for scanning the layer with the laser beam, i.e., for relatively moving the laser beam, to apply patterning to the layer in a manner to form the layer in the predetermined shape as well as the process for printing the predetermined shaped portion of the layer to another surface.

Alternatively, the laser process is defined as a process for scanning a light-heat converting layer with the laser beam, i.e., for relatively moving the laser beam, to print the predetermined shaped portion of the layer located on the light-heat converting layer to another surface.

2. Semiconductor Layer

A donor substrate D1 shown in an upper portion of FIG. 1C is prepared next. The donor substrate D1 has a base substrate 32, an ablation layer 42 located on the base substrate 32, and a donor-side semiconductor layer 61 located on the ablation layer 42. Herein, the base substrate 32 is permeable to light of wavelengths in the infrared region at least. In this embodiment, the base substrate 32 is made from a plurality of polyester films mutually laminated. The ablation layer 42 is the same as the aforementioned ablation layer 41. On the other hand, the donor-side semiconductor layer 61 is made from an F8T2 (a fluorene-thiophene copolymer). The donor-side semiconductor layer 61 has a thickness of approximately 1 μm.

Herein, one example of a method for forming the donor-side semiconductor layer 61 is as follows. Firs, the ablation layer 42 is coated with a decalin solution of F8T2, and the decalin solution used for coating is dried. F8T2 is precipitated in this manner, thereby being able to obtain the donor-side semiconductor layer 61. In the meanwhile, it is possible to form a donor-side semiconductor 61 made of low molecules such as pentacene, rubrene, phthalocyanine, and the like, by an deposition method instead of the formation method as described above.

Next, a semiconductor 61g in contact with the source electrode 51s and the drain electrode 51d is formed over the laser process, as shown in FIG. 1C to FIG. 1D. Detailed particulars are as follows.

First, the prepared donor substrate D1 and the element-side substrate 10A are mutually overlaid. In this bout, the donor substrate D1 is oriented with respect to the element-side substrate 10A in a manner that the donor-side semiconductor layer 61 faces the source electrode 51s and the drain electrode 51d. In this situation, the ablation layer 42 is irradiated with the laser beam L2 through the base substrate 32 by using the aforementioned laser apparatus.

On the ablation layer 42, the ablation is then caused at a portion on which the laser beam L2 is incident, so that a corresponding portion of the donor-side semiconductor layer 61 is separated from the donor substrate D1. Herein, the corresponding portion of the donor-side semiconductor layer 61 is printed to the element-side substrate 10A since the donor substrate D1 and the element-side substrate 10A are overlaid. Thus, the ablation layer 42 is irradiated with the laser beam L2 in accordance with a shape of the semiconductor layer 61g to be formed over this process. It is to be noted that the laser beam L2 may be the same in wavelength as the laser beam L1 since the ablation layer 42 is identical to the ablation layer 41.

According to FIG. 11C and FIG. 1D, the ablation layer 42 is scanned with the laser beam L2 so that the entire donor-side semiconductor layer 61 is printed. In this regard, the ablation layer 42 may be scanned with the laser beam L2 so that only one part of the donor-side semiconductor layer 61 is printed, as long as the semiconductor layer 61g to be obtained is in contact with the source electrode 51s and the drain electrode 51d while facing a gate electrode 52g to be described hereinafter.

It is preferable that the ablation layer 42 is scanned with the laser beam L2 in a direction from one side to the other side of the source electrode 51s and the drain electrode 51d. Furthermore, irradiation of the laser beam L2 is preferably kept in succession during the period of scan in a direction from one side to the other side. Thus, any interfaces perpendicular to an electron moving direction are not caused in the semiconductor layer 61g corresponding to the single TFT in this manner.

As shown in FIG. 1D, the semiconductor 61g in contact with the source electrode 51s and the drain electrode 51d is formed by printing the donor-side semiconductor layer 61 as described above. In the meanwhile, the ablation layer 42 is located on the semiconductor layer 61g since the ablation layer 42 is printed as a sacrifice layer along with the donor-side semiconductor layer 61 in this embodiment.

The semiconductor layer 61g is made from F8T2 as described above. F8T2 is one of polymer semiconductor materials. PT(polythiophene), polypyrrole, polyacetylene, PTV, PPV, PNV, PAA, BBL, and the like may be used as the polymer semiconductor material other than F8T2. According to the production method in this embodiment, it is not necessary to substantially modify a structure of the laser apparatus even in a case of a low molecular semiconducting material composing the semiconductor layer 61g, as long as the donor substrate D1 is available, that is, prepared. To be more specific, pentacene type, rubrene type, fullerene type, phthalocyanine type, TCNQ, and the like may be used as the low molecular semiconducting material.

As is clear from the above explanation, a portion necessary for the semiconductor layer 61g is printed out of the donor-side semiconductor layer 61 from the donor substrate D1 to the element-side substrate 10A. The portion which is not printed from the donor substrate D1 to the element-side substrate 10A may be printed as the semiconductor layer 61g of the TFT of another element-side substrate 10A. Herein, in order to print to the other element-side substrate 10A the portion which is not printed, it is enough to shift a relative positional relationship between the other element-side substrate 10A and the donor substrate D1 at the time of overlaying those substrates from that between the previous element-side substrate 10A and the donor substrate D1 at the time of overlaying those substrates. Therefore, the amount of semiconducting material to be discarded as a surplus in shaping the semiconductor layer 61g can be reduced differently from both the deposition method and the printing method in this embodiment. It is therefore possible to realize the earth-conscious production process.

In a meanwhile, established in a conventional photolithography process is such an art that the patterning is applied to the semiconductor layer while the highly accurate alignment of the semiconductor layer is realized. The photolithography, however, is not applied to the photoconductor layer made from the organic semiconducting material. Therefore, the patterning is generally applied to the semiconductor layer made from the organic semiconducting material by using the mask deposition method or the printing method instead of the photolithography process. Herein, either the mask deposition method or the printing method is selected in accordance with a type of the organic semiconducting material but it is difficult to obtain sufficient alignment accuracy in a case of the printing method. That is, the alignment accuracy is determined by the difference of the organic semiconducting material. In this embodiment, however, the laser process is used to shape the semiconductor layer 61g in this embodiment, so that the semiconductor 61g can be aligned with high accuracy with respect to other constituent elements in the TFT regardless of a type of the material composing the semiconductor layer 61g.

3. Gate Insulating Layer

A donor substrate D2 shown in an upper portion of FIG. 2A is prepared next. The donor substrate D2 has a base substrate 33, an ablation layer 43 located on the base substrate 33, and an insulating layer 71 located on the ablation layer 43. Herein, the base substrate 33 is the same as the aforementioned base substrate 32. Furthermore, the ablation layer 43 is the same as the aforementioned ablation layer 41. Yet further, the insulating layer 71 in this embodiment is made from polyvinylphenol (PVP). The insulating layer 71 has a thickness of 5 μm.

As shown in FIG. 2A and FIG. 2B, a gate insulating layer 71g overlaid on the semiconductor layer 61g is formed over the laser process. Detailed particulars are as follows.

First, the prepared donor substrate D2 and the element-side substrate 10A are mutually overlaid. In this bout, the donor substrate D1 is oriented with respect to the element-side substrate 10A so that the insulating layer 71 faces the ablation layer 42. In this situation, the ablation layer 43 is irradiated with the laser beam L3 through the base substrate 33 by using the aforementioned laser apparatus.

The ablation is caused at a portion of the ablation layer 43, on which the laser beam L3 is incident, so that a corresponding portion of the insulating layer 71 is separated from the donor substrate D2. Herein, the corresponding portion of the insulating layer 71 is printed to the element-side substrate 10A since the donor substrate D2 and the element-side substrate 10A are overlaid. In this regard, the laser beam L3 is set to irradiate the ablation layer 43 in accordance with a shape of the gate insulating layer 71g to be formed in this process. It is to be noted the ablation layer 43 is the same as the ablation layer 41, so that laser beam L3 may be the same in wavelengths as the laser beam L1.

According to FIG. 2A and FIG. 2B, the ablation layer 43 is irradiated with the laser beam L3 in a manner to print the entire region of the insulating layer 71. However, the ablation layer 43 may be scanned with the laser beam L3 in a manner to print only one part of the insulating layer 71 as long as the gate insulating layer 71g to be obtained is located between the semiconductor layer 61g and the gate electrode 52g.

As shown in FIG. 213, the gate insulating layer 71g overlaid on the semiconductor 61g is formed by printing the insulating layer 71 as described above. It is to be noted that the ablation layer 43 is printed along with the insulating layer 71 in this embodiment, so that the ablation layer 43 is located on the gate insulating layer 71g.

As is clear from the above explanation, a portion necessary for the gate insulating layer 71g is printed out of the insulating layer 71 from the donor substrate D2 to the element-side substrate 10A. A portion which is not printed from the donor substrate D2 to the element-side substrate 10A, may be printed as the gate insulating layer 71g of another element-side substrate 10A. Herein, in order to print to the other element-side substrate 10A a portion which is not printed, it is enough to shift a relative positional relationship between the other element-side substrate 10A and the donor substrate D2 at the time of overlaying those substrates from that between the previous element-side substrate 10A and the donor substrate D2 at the time of overlaying those substrates. Thus, the amount of insulating material to be discarded as a surplus in shaping the gate insulating layer 71g can be reduced differently from both the deposition method and the printing method in this embodiment. It is therefore possible to realize the earth-conscious production process.

4. Gate Electrode

A donor substrate D3 shown in an upper portion of FIG. 2C is prepared next. Herein, the donor substrate D3 has a base substrate 34, an ablation layer 44 located on the base substrate, and a conductive layer 52 located on the ablation layer 44. The base substrate 34 is the same as the base substrate 32. Furthermore, the ablation layer 44 is the same as the ablation layer 41. The conductive layer 52 is made from chrome and is formed by the deposition method. The conductive layer 52 has a thickness of approximately 1.5 nm.

As shown in FIG. 2C and FIG. 2D, the gate electrode 52g superposed on the semiconductor layer 61g is formed over the laser process. Detailed particulars are as follows.

The prepared donor substrate D3 and the element-side substrate 10A are mutually overlaid first. In this bout, the donor substrate D3 is oriented with respect to the element-side substrate 10A so that the conductive layer 52 faces the ablation layer 43. In this situation, the ablation layer 44 is irradiated with a laser beam L4 through the base substrate 34 by using the laser apparatus.

On the ablation layer 44, the ablation is then caused at a portion on which the laser beam L4 is incident, so that a corresponding portion of the conductive layer 52 is separated from the donor substrate D3. Herein, the corresponding portion of the conductive layer 52 is printed to the element-side substrate 10A since the donor substrate D3 and the element-side substrate 10A are overlaid. In this regard, the laser beam L4 is set to irradiate the ablation layer 44 in accordance with a shape of the gate electrode 52g to be formed over this process. It is to be noted that the laser beam L4 may be the same in wavelength as the laser beam L1 since the ablation layer 44 is identical to the ablation layer 41.

As shown in FIG. 2D, the gate electrode 52g superposed on the semiconductor Gig is formed by printing the conductive layer as described above. In the meanwhile, the ablation layer 44 is located on the gate electrode 52g since the ablation 44 is printed along with the conductive layer 52.

As is clear from the above explanation, a portion necessary for the gate electrode 52g is printed out of the conductive layer 52 from the donor substrate D3 to the element-side substrate 10A. The portion which is not printed from the donor substrate D3 to the element-side substrate 10A may be printed as the gate electrode 52g of TFT 90 of another element-side substrate 10A. Herein, in order to print to the other element-side substrate 10A the portion which is not printed, it is enough to shift a relative positional relationship between the other element-side substrate 10A and the donor substrate D3 at the time of overlaying those substrates from that between the previous element-side substrate 10A and the donor substrate D3 at the time of overlaying those substrates. Therefore, the amount of conducting material to be discarded as a surplus in shaping the gate electrode 52g can be reduced differently from both the deposition method and the printing method. It is therefore possible to realize the earth-conscious production process.

The TFT can be obtained by four laser processes according to this embodiment. The semiconductor layer 61g can be formed in the laser process according to this embodiment, thereby being able to be formed without depending on the material composing the semiconductor layer 61g. Furthermore, the laser beams L1, L2, L3, and L4 having the same wavelength can be used because the ablation layers 41, 42, 43, and 44 are all the same. In another words, the TFT 90 can be formed by the single identical laser apparatus as long as the electro-side substrate 10A and the donor substrates D1, D2, and D3 are available, i.e., prepared.

### Second Embodiment

Explained in this embodiment is a case where a method for forming the thin-film transistor according to the second embodiment of the invention is applied to produce a TFT of a bottom gate type. In this embodiment, it is to be noted that the same reference numbers are assigned to the constituent elements approximately same as those in the first embodiment.

1. Gate Electrode

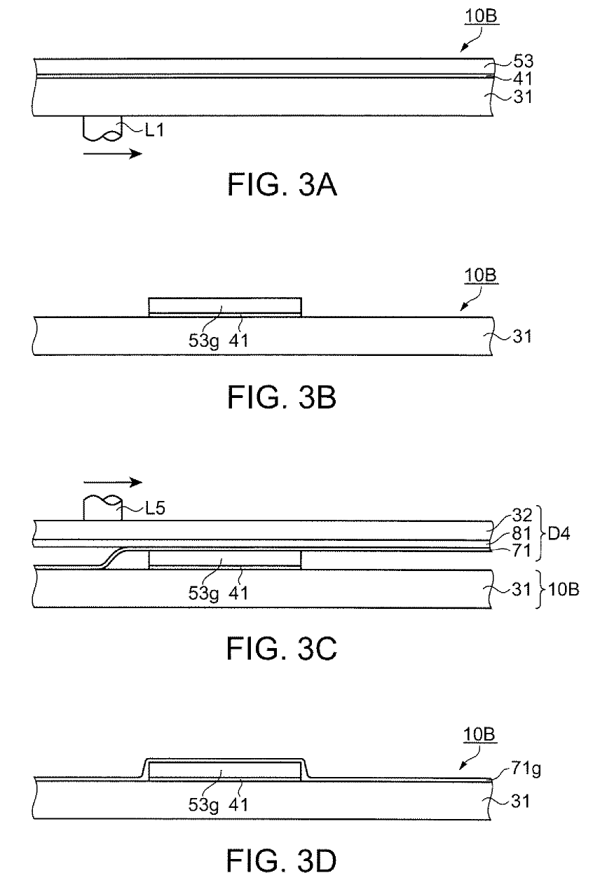

An element-side substrate 10B shown in FIG. 3A is prepared first. The element-side substrate 10b has the base substrate 31, the ablation layer 41 located on the base substrate 31, and the conductive layer 53 located on the ablation layer 41. Herein, a structure of the element-side substance 10B in the situation shown in FIG. 3A is the same as a structure of the element-side substrate 10A explained referring FIG. 1A except a thickness of the conducting layer 53. A thickness of the conductive layer 53 is of approximately 2 μm.

Next, a gate electrode 53g is formed over the laser process as shown in FIG. 3A and FIG. 3B. The laser process for forming the gate electrode 53g is basically the same as that for forming the source electrode 51s and the drain electrode 51d in the first embodiment. However, this embodiment is different form the first embodiment in that the laser beam L1 is set to irradiate in a manner to eliminate the conductive layer 53 with the gate electrode 53g remaining. As described above, the use of the laser process renders the resist and the photomask unnecessary at the time of application of patterning to the gate electrode 53g. It is to be noted that the ablation layer 41 remains between the gate electrode 53g to be obtained and the base substrate 31 according to the laser process in this embodiment.

2. Gate Insulating Layer

Next, a donor substrate D4 shown in an upper portion of FIG. 3C is prepared. Herein, the donor substrate D4 has the base substrate 32, a light-heat converting layer 81 located on the base substrate 32, and an insulating layer 71 located on the light-heat converting layer 81. The base substrate is permeable to light of wavelengths in the infrared region as described in the first embodiment. The light-heat converting layer 81 is defined as a layer for converting energy of the laser light irradiation into heat. An optical density of the light-heat converting layer 81 may be from 0.2 to 3 in a wavelength range of a laser beam L5. Carbon black or graphite is preferably used as a material of the light-heat converting layer 81. In a case of using the wavelengths in the infrared region, the effective light-heat converting layer 81 can be obtained by using an infrared absorbing pigment other than carbon black or graphite. To be more specific, phthalocyanine dye, naphthalocyanine dye, anthraquinone dye, indolenine dye, polymethine dye, squarylium dye, cyanine dye, metal complex dyestuff, azo cobalt complex dyestuff, thiol nickel complex dye, triarylmethane dye, immonium dye, naphthoquinone dye, anthracene dye, azulene dye, phthalide dye, and the like may be used. As explained in the first embodiment, the insulating layer 71 is defined as a layer made from the polyvinylphenol (PVP).

As shown in FIG. 3C and FIG. 3D, a gate insulating layer 71g covering the gate electrode 43g is formed over the laser process. Detailed particulars are as follows.

First, the prepared donor substrate D4 and the element-side substrate 10B are overlaid each other. In this bout, the donor substrate D4 is oriented with respect to the element-side substrate 10B in a manner that the insulating layer 71 faces the gate electrode 53g. In this situation, the light-heat converting layer 81 is irradiated with the laser beam L5 through the base substrate 32 by using the aforementioned laser apparatus according the first embodiment. To be more specific, the laser beam L5 is set to irradiate the light-heat converting layer 81 in accordance with a shape of the gate insulating layer 71g to be formed. In this manner, a portion of the light-heat converting layer 81, on which the laser beam L5 is incident, causes heating to melt and weld a corresponding portion of the insulating layer 71 onto the element-side substrate 10B, so that the insulating layer 71 is separated from the light-heat converting layer 81 at the time of stripping off the donor substrate D4. Herein, the corresponding portion of the insulating layer 71 is printed to the element-side substrate 10B since the donor substrate D4 and the element-side substrate 10B are overlaid each other.

According to FIG. 3C and FIG. 3D, the light-heat converting layer 81 is scanned with the laser beam L5 so that the entire region of the insulating layer 71 is printed. In this regard, the light-heat converting layer 81 may be scanned with the laser beam L5 so that only one part of the insulating layer 71 is printed as long as the gate insulating layer 71g to be obtained is located between the gate electrode 53g and a channel region of the semiconductor layer 61g to be described hereinafter.

As shown in FIG. 3D, the gate insulating layer 71g is formed on the gate electrode 53g by printing the insulating layer as described above.

As is clear from the above explanation, a portion necessary for the gate insulating layer 71g is printed out of the insulating layer 71 from the donor substrate D4 to the element-side substrate 10B. Thus, the amount of insulating material to be discarded as a surplus in shaping the gate insulating layer 71g can be reduced for the same reason as that explained in reference to the gate insulating layer 71g in the first embodiment. It is therefore possible to realize the earth-conscious production process.

3. Semiconductor layer

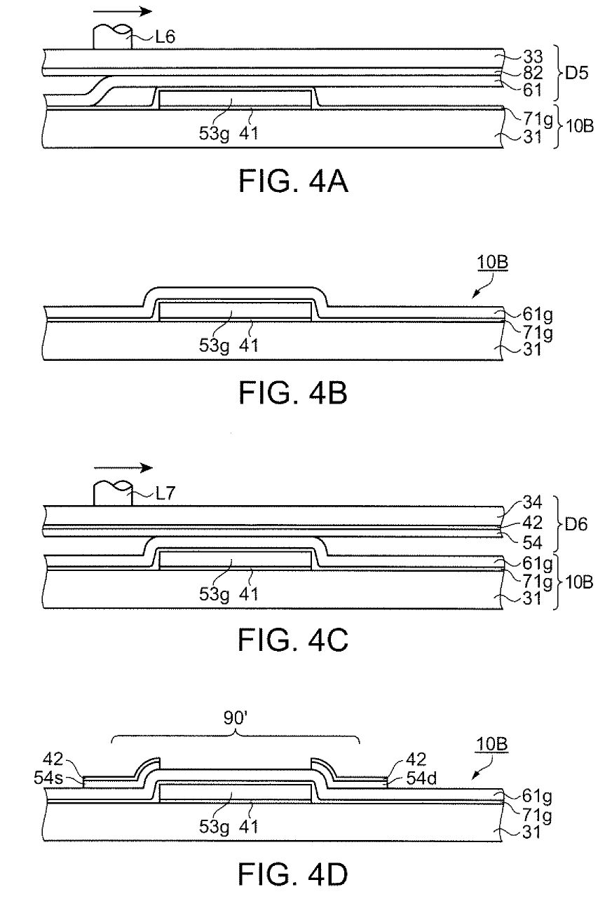

Next, a donor substrate D5 shown in an upper side of FIG. 4A is prepared. Herein, the donor substrate D5 has the base substrate 33, a light-heat converting layer 82 located on the base substrate 33, and the donor-side semiconductor layer 61 located on the light-heat converting layer 82.

The semiconductor layer 61g is formed on the gate insulating layer 71g over the laser process as shown in FIG. 4A and FIG. 4B. Detailed particulars are as follows.

First, the prepared donor substrate D5 and the element-side substrate 10B are overlaid each other. In this bout, the donor substrate D5 is oriented with respect to the element-side substrate 10B so that the donor-side semiconductor layer 61 faces the gate insulating layer 71g. In this situation, the light-heat converting layer 82 is irradiated with a laser beam L6 through the base substrate 33 by using the aforementioned laser apparatus. Herein, the laser beam L6 is set to irradiate the light-heat converting layer 82 in accordance with a shape of the semiconductor layer 61g to be formed. A corresponding portion of the donor-side semiconductor layer 61 is then printed to the element-side substrate 10B on the same principal as that for printing the gate insulating layer 71g.

According to FIG. 4A and FIG. 4B, the light-heat converting layer 82 is scanned with the laser beam L6 so that the entire region of the donor-side semiconductor layer 61 is printed. In this regard, the light-heat converting layer 82 may be scanned with the laser beam L6 so that only one part of the donor-side semiconductor layer 61 is printed as long as the semiconductor layer 61g to be obtained faces a gate electrode 53g while being in contact with a source electrode 54s and the drain electrode 54d to be described later.

It is preferable that the light-heat converting layer 82 is scanned with the laser beam L6 in a direction from one side to the other side of the source electrode 54s and the drain electrode 54d to be described later. Furthermore, irradiation of the laser beam L6 is preferably kept in succession during the period of scan in a direction from one side to the other side. Thus, any interfaces perpendicular to an electron moving direction are not caused in the semiconductor layer 61g corresponding to the single TFT in this manner.

The semiconductor layer 61g is formed on the gate insulating layer 71g by printing the donor-side semiconductor layer 61 in this manner as shown in FIG. 4B.

The semiconductor layer 61g is made from F8T2 as described in the first embodiment. F8T2 is one of polymer semiconductor materials. PT(polythiophene), polypyrrole, polyacetylene, PTV, PPV, PNV, PAA, BBL, and the like may be used as the polymer semiconductor material other than F8T2. According to the production method in this embodiment, it is not necessary to substantially modify a structure of the laser apparatus even in a case of changing the material composing the semiconductor layer into the low molecular semiconducting material, as long as the donor substrate is available, that is, prepared. To be more specific, pentacene type, rubrene type, fullerene type, phthalocyanine type, TCNQ, and the like may be used as the low molecular semiconducting material. In a case of using the low molecular semiconducting material, it is to be noted that one part of the donor-side semiconductor 61 may be printed not by necessarily being welded likewise a case of the insulating layer or the semiconductor layer made from polymer semiconductor material, but by being evaporated onto the facing insulating layer upon vaporization or sublimation because of the heat caused at the light-heat converting layer 82.

As is clear from the above-explanation, a portion necessary for the semiconductor layer 61g is printed out of the donor-side semiconductor layer 61 from the donor substrate D5 to the element-side substrate 10B. Thus, the amount of insulating material to be discarded as a surplus in shaping the semiconductor layer 61g can be reduced for the same reason as that explained in reference to the semiconductor layer 61g in the first embodiment. It is therefore possible to realize the earth-conscious production process.

As explained in the first embodiment, the use of the laser process in shaping the semiconductor layer 61g makes it possible to align the semiconductor 61g with high accuracy with respect to other constituent elements in the TFT regardless of a type of the material composing the semiconductor layer 61g.

4. Source Electrode and Drain Electrode

First, a donor substrate D6 as shown in an upper portion of FIG. 4C is prepared. The donor substrate D6 has the base substrate 34, the ablation layer 42 located on the base substrate 34, and a conductive layer 54 located on the ablation layer 42. The ablation layer 42 is the same as the ablation layer 41 in the first embodiment. The conductive layer is made from chrome.

As shown in FIG. 4C and FIG. 4D, the source electrode 54s and the drain electrode 54d are formed on the semiconductor layer 61 over the laser process. Detailed particulars are as follows.

The prepared donor substrate D6 and the element-side substrate 10B are first overlaid each other. In this bout, the donor substrate D6 is oriented with respect to the element-side substrate 10B so that the conductive layer 54 faces the semiconductor layer 61g. In this situation, the ablation layer 42 is irradiated with a laser beam L7 through the base substrate 34 by using the laser apparatus. Herein, the laser beam L7 is set to irradiate the ablation layer 42 in accordance with shapes of the source electrode 54s and the drain electrode 54d to be formed. A corresponding portion of the conductive layer 54 is then printed to the element-side substrate 10B on the same principal as that for printing the gate insulating layer 52g.

The source electrode 54s and the drain electrode 54d as shown in FIG. 4D are obtained by printing the conductive layer 54 as described above. In the meanwhile, the ablation layer 42 is printed along with the conductive layer 54. Therefore, the ablation layer 42 is located on each of the source electrode 54s and the drain electrode 54d.

As is clear from the above description, a portion necessary for the source electrode 54s and the drain electrode 54d is printed out of the conductive layer 54 from the donor substrate D6 to the element-side substrate 10B. Thus, the amount of conductive material to be discarded as a surplus in shaping the source electrode 54s and the drain electrode 54d can be reduced for the same reason as that explained in reference to the gate electrode 54d in the first embodiment. It is therefore possible to realize the earth-conscious production process.

### MODIFICATION EXAMPLE 1

According to the first and second embodiments, the source electrodes 51s, 54s, the drain electrodes 51d, 54d, the semiconductor layer 61g, the gate insulating layer 71g, and the gate electrodes 52g, 53g are formed over the laser processes, respectively. However, the invention is not limited to those embodiments. To be more specific, at least the semiconductor layer 61g may be formed over the laser process. Furthermore, the other the source electrodes 51s, 54s, the drain electrodes 51d, 54d, the gate insulating layer 71g, and the gate electrodes 52g, 53g may be formed by the conventional production method. However, where all of the constituent elements in the TFT are formed by using the laser process, there is such an advantage that any modification is substantially unnecessary for the laser process even where a material of any constituent element is changed.

### MODIFICATION EXAMPLE 2

The conductive layers 51, 52 are made from chrome in the first embodiment. However, the invention is not limited to this embodiment. To be specific, the conductive layers 51, 52 may be made from other metal such as Ag, or other conductive polymer such as poly (3,4-ethylenedioxythiophene) (PEDOT).

Furthermore, the source electrode 51s and the drain electrode 51d are shaped by irradiating the ablation layer 41 with the laser beam L1 through the base substrate 31 in the first embodiment. However, in a case of the conductive layer 51 made from silver or PEDOT, the conductive layer 51 is permeable to light of wavelengths in the infrared region, so that the laser beam L1 may be set to irradiate the ablation layer 41 through the conductive layer 51. The laser beam L1 may be set to radiate in either direction with respect to the base substrate 31 as long as a beam spot of the laser beam L1 can be incident on the ablation layer 41, as described above. The second embodiment is the same upon this point.

### MODIFICATION EXAMPLE 3

According to those embodiments, each constituent element in the TFT is shaped by using the ablation layers 41, 42, 43, 44, or the light-heat converting layers 81, 82 so that an existing CTP (Computer To Plate) system can be used as the aforementioned laser apparatus. A structure of the CTP system to be used may be either a drum type or a flat bed type. In a case of using the CTP system of the drum type, the element-side substrate 10A and the donor substrate D1 (D2, D3, D4, D5, D6) mutually overlaid are wound around the drum under a high-vacuum. As the drum is rotated, the laser beam may be set to irradiate the element-side substrate 10A or the donor substrate D1 on the rotated drum. The aforementioned merits of using the laser process can be obtained without designing a new laser apparatus in this manner. In the meanwhile, TrendSetter (a trademark of Creo Inc.) is exemplified as the CTP system used as the laser apparatus.

Furthermore, a beam spot diameter on each of the ablation layers 41, 42, 43, 44, or the light-heat converting layers 81, 82 is of 15 μm, as described above. In this regard, the beam spot diameter is not limited to this value but may be arbitrarily changed in accordance with a combination of an apparatus and a material. In a case of using the existing CTP system, for example, the beam spot diameter can be arbitrarily changed in a range of 5 μm to 20 μm. In a case of using a system other than the existing CTP system, a light source or a scan optical system may be adjusted in a manner to set the beam spot diameter to submicron order.

1. A method for forming a thin-film transistor, comprising:
forming a source electrode and a drain electrode on an element-side substrate;
forming a semiconductor layer in contact with the source electrode and the drain electrode;
forming a gate insulating layer overlaid on the semiconductor layer; and
forming a gate electrode overlaid on the gate insulating layer,
wherein the semiconductor layer is formed over a laser process at the step of forming the semiconductor layer in contact with the source electrode and the drain electrode.

2. The method for forming the thin-film transistor according to claim 1, wherein a first donor substrate having a first base substrate, a first ablation layer on the first base substrate, and a donor-side semiconductor layer on the first ablation layer is overlaid on the element-side substrate, and the first ablation layer is irradiated with a first laser beam in a manner to print at least one part of the donor-side semiconductor layer from the first donor substrate to the element-side substrate to obtain the semiconductor layer at the step for forming the semiconductor in contact with the source electrode and the drain electrode.

3. The method for forming the thin-film transistor according to claim 1, wherein the element-side substrate having a substrate, a second ablation layer on the substrate, and a first conductive layer on the second ablation layer is prepared, and the second ablation layer is irradiated with a second laser beam in a manner to strip a portion other than the source electrode and the gate electrode off the first conductive layer at the step of forming the source electrode and the drain electrode on the element-side substrate.

4. The method for forming the thin-film transistor according to claim 1, wherein a second donor substrate having a second base substrate, a third ablation layer on the second base substrate, and an insulating layer on the third ablation layer is overlaid on the element-side substrate, and the third ablation layer is irradiated with a third laser beam in a manner to print at least one part of the insulating layer from the second donor substrate to the element-side substrate to obtain the gate insulating layer at the step of forming the gate insulating layer overlaid on the semiconductor layer.

5. The method for forming the thin-film transistor according to claim 1, wherein a third donor substrate having a third base substrate, a fourth ablation layer on the third base substrate, and a second conductive layer on the fourth ablation layer is overlaid on the element-side substrate, and the fourth ablation layer is irradiated with a fourth laser beam in a manner to print at least one part of the second conductive layer from the third donor substrate to the element-side substrate to obtain the gate electrode at the step of forming the gate electrode overlaid on the gate insulating layer.

6. A method for forming a thin-film transistor, comprising the steps of:
forming a gate electrode on an element-side substrate;
forming a gate insulating layer on the gate electrode;
forming a semiconductor layer overlaid on the gate electrode; and
forming a source electrode and a drain electrode in contact with the semiconductor layer, respectively,
wherein the semiconductor layer is formed over a laser process at the step of forming the semiconductor layer overlaid on the gate electrode.

7. The method for forming the thin-film transistor according to claim 6, wherein a first donor substrate having the first base substrate, a first light-heat converting layer on the first base substrate, and a donor-side semiconductor layer on the first light-heat converting layer is overlaid on the element-side substrate, and the first light-heat converting layer is irradiated with a first laser beam in a manner to print at least one part of the donor-side semiconductor layer from the first donor substrate to the element-side substrate to obtain the semiconductor layer at the step of forming the semiconductor layer overlaid on the gate electrode.

8. The method for forming the thin-film transistor according to claim 6, wherein the element-side substrate having a substrate, a first ablation layer on the substrate, and a first conductive layer on the first ablation layer is prepared, and the first ablation layer is irradiated with a second laser beam in a manner to strip a portion other than the gate electrode off the first conductive layer at the step of forming the gate electrode on the element-side substrate.

9. The method for forming the thin-film transistor according to claim 6, wherein a second donor substrate having a second base substrate, a light-heat converting layer on the second base substrate, and an insulating layer on the light-heat converting layer is overlaid on the element-side substrate, and the light-heat converting layer is irradiated with a third laser beam in a manner to print at least one part of the insulating layer from the second donor substrate to the element-side substrate to obtain the gate insulating layer at the step of forming the gate insulating layer on the gate electrode.

10. The method for forming the thin-film transistor according to claim 6, wherein a third donor substrate having a third base substrate, a second ablation layer on the third base substrate, and a second conductive layer on the second ablation layer is overlaid on the element-side substrate, and the second ablation layer is irradiated with a fourth laser beam in a manner to print at least one part of the second conductive layer from the third donor substrate to the element-side substrate at the step of forming the source electrode and the drain electrode in contact with the semiconductor layer, respectively.
